(19) United States
(12) Patent Application Publication
(10) Pub. No.: US 2004/0171260 A1
(43) Pub. Date: Sep. 2, 2004

(54) Line edge roughness control

(75) Inventors: Youngjin Choi, Pleasanton, CA (US); Helen H. Zhu, Fremont, CA (US); Sangheon Lee, Milpitas, CA (US); Sean S. Kang, Fremont, CA (US)

Correspondence Address: BEYER WEAVER & THOMAS LLP, P.O. BOX 778, BERKELEY, CA, 94704-0778, US

(73) Assignee: Lam Research Corporation

(21) Appl. No.: 10/798,456

(22) Filed: Mar. 10, 2004

Related U.S. Application Data
(63) Continuation-in-part of application No. 10/170,424, filed on Jun. 14, 2002.

(30) Foreign Application Priority Data
Jun. 14, 2002 (US) 2003/0232504 A1

(51) Int. Cl. H01L 21/302; H01L 21/461

(52) U.S. Cl. 438/689

(57) ABSTRACT

A method for etching a layer through a photoresist mask with an ARC layer between the layer to be etched and the photoresist mask over a substrate is provided. The substrate is placed into a processing chamber. An ARC open gas mixture is provided into the processing chamber. The ARC open gas mixture comprises an etchant gas and a polymerization gas comprising CO and CH₃F. An ARC open plasma is formed from the ARC open gas mixture. The ARC layer is etched with the ARC open plasma until the ARC layer is opened. The ARC open gas mixture stopped before the layer to be etched is completely etched.

### RELATED APPLICATIONS

This application is a continuation-in-part of U.S. patent application Ser. No. 10/170,424 (Attorney Docket No. P0930) which published as US 2003/0232504 A1, entitled “Process For Etching Dielectric Films With Improved Resist And/Or Etch Profile Characteristics,” by Eppler et al. filed Jun. 14, 2002, and which is incorporated by reference for all purposes.

### BACKGROUND OF THE INVENTION

1. Field of the Invention

The invention relates to semiconductor devices. More specifically, the invention relates to the production of semiconductor devices with reduced line edge roughness.

2. Description of the Related Art

In the formation of semiconductor devices, line edge roughening increases the critical dimensions of the devices. In addition, uneven etching results across a wafer surface may further increase critical dimensions.

### SUMMARY OF THE INVENTION

To achieve the foregoing and in accordance with the purpose of the present invention, a method for etching a layer through a photoresist mask with an ARC layer between the layer to be etched and the photoresist mask over a substrate is provided. The substrate is placed into a processing chamber. An ARC open gas mixture is provided into the processing chamber. The ARC open gas mixture comprises an etchant gas and a polymerization gas comprising CO and CH₃F. An ARC open plasma is formed from the ARC open gas mixture. The ARC layer is etched with the ARC open plasma until the ARC layer is opened. The ARC open gas mixture stopped before the layer to be etched is completely etched.

In another manifestation of the invention a method for forming a semiconductor device is provided. A layer to be etched is placed over a substrate. An organic ARC layer is formed over the layer to be etched. A photoresist mask is formed over the ARC layer. The substrate into is placed into a processing chamber. An ARC open gas mixture is provided into the processing chamber. The ARC open gas mixture comprises an etchant gas and a polymerization gas comprising CO and CH₃F. An ARC open plasma is formed from the ARC open gas mixture. The ARC layer is etched with the ARC open plasma until the ARC layer is opened. The ARC open gas mixture is stopped, so that none of the layer to be etched is etched by the ARC open plasma. An etch plasma different than the ARC open plasma is provided. The layer to be etched is etched with the etch plasma.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart for forming a feature in a dielectric layer, which uses an inventive antireflective coating (ARC) open process.

FIGS. 2A-C are cross-sectional views of an etch layer over a substrate during the formation of features using the inventive ARC open process.

FIG. 3 is a more detailed flow chart of a step of the opening of the ARC layer.

FIG. 4 is a schematic view of a process chamber that may be used in a preferred embodiment of the invention.

FIGS. 5A and 5B illustrate a computer system, which is suitable for implementing a controller.

FIGS. 6A-B are cross-sectional views of an etch layer over a substrate after an ARC opening is performed.

FIGS. 7A-B are cross-sectional views of an etch layer over a substrate after features have been etched into the etch layer.

FIGS. 8A-B are cross-sectional views of an etch layer over a substrate after an ARC opening is performed using a prior art ARC open process.

FIGS. 9A-B are cross-sectional views of an etch layer over a substrate after features have been etched into the etch layer after a prior art ARC open process has been used.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

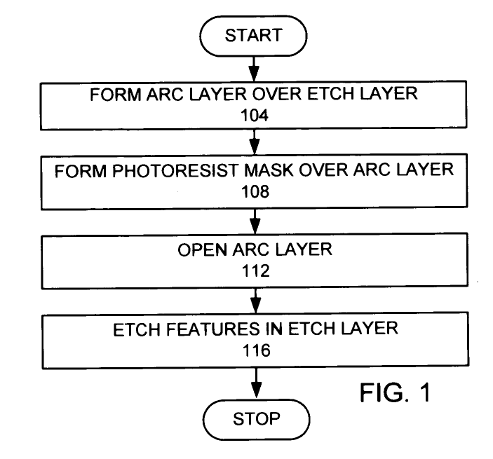

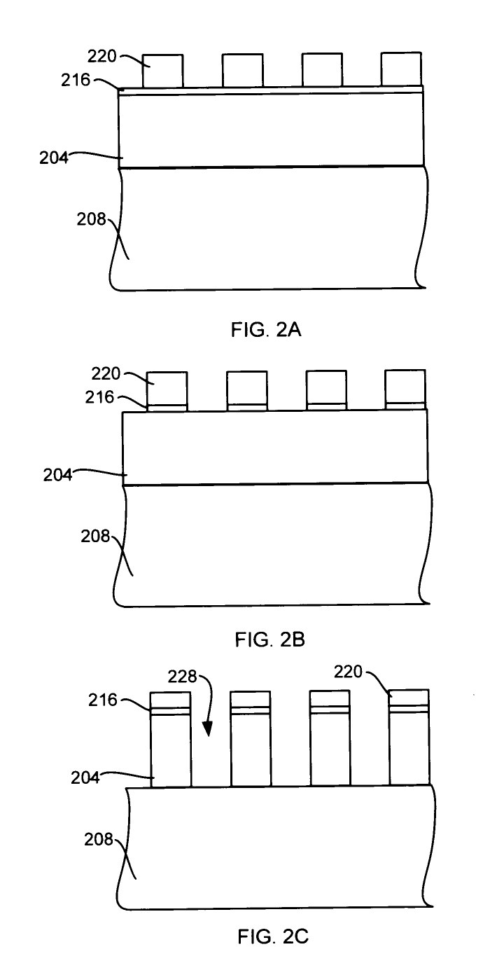

To facilitate understanding. FIG. 1 is a high level flow chart for forming a feature in a dielectric layer, which uses the inventive antireflective coating (ARC) open process. An ARC layer is formed over an etch layer, which is a layer to be etched (step 104). FIG. 2A is a cross-sectional view of an etch layer 204 over a substrate 208. An ARC layer 216 has been formed over the etch layer 204. A photoresist mask 220 is formed over the ARC layer 216 (step 108). The ARC layer is opened (step 112). FIG. 2B is a cross-sectional view of the ARC layer 216 after it is opened. Features 228 are then etched into the etch layer 212 through the photoresist mask 220 and the ARC layer 216, as shown in FIG. 2C. The photoresist mask 220 and ARC layer 216 may be completely removed during a subsequent photoresist stripping process.

Although the etch layer 204 is show as being on top of the substrate 208, one or more layers may be between the etch layer 204 and the substrate 208. Alternatively, the substrate may be the etch layer.

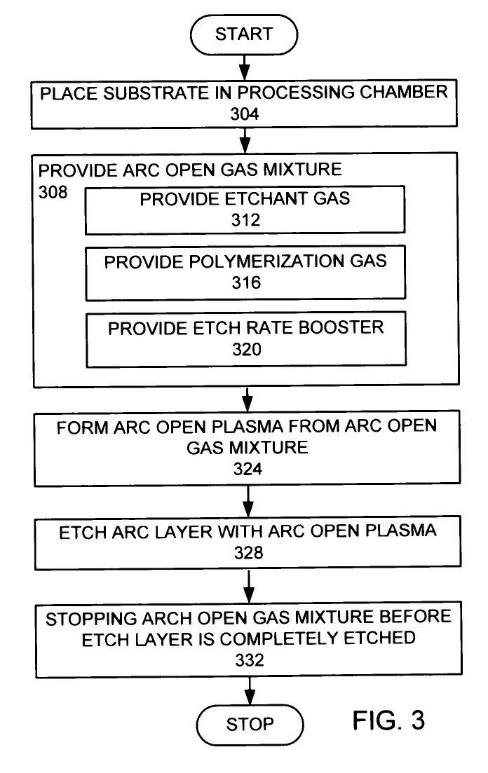

FIG. 3 is a more detailed flow chart of the step of opening the ARC layer (step 112). The substrate is placed in a processing chamber (step 304). This step may occur before the step of opening the ARC layer (step 112). An ARC open gas mixture is provided into the processing chamber (step 308). This step comprises providing an etchant gas to the processing chamber (step 312), providing a polymerization gas to the processing chamber (step 316), and providing an etch rate booster to the processing chamber (step 320). The polymerization gas is CO and CH₃F. The etch rate booster is O₂.

### EXAMPLE

In an example of the invention, the etch layer 204 is a is a silicon oxide dielectric layer over a silicon wafer substrate 208. The ARC layer is a bottom antireflective coating (BARC), which is an organic ARC material. It is preferred that BARC be similar to photoresist, so that the BARC have similar stripping characteristics. In other embodiments, the ARC layer may be made of other organic materials to form an organic ARC layer. The photoresist mask 220 is made of 193 photoresist. In other examples the photoresist mask may be of 193 and higher generation photoresist masks. Such mask materials may be soft and therefore cause line edge roughening or non-uniform etching. The invention is able to compensate for such soft photoresist materials.

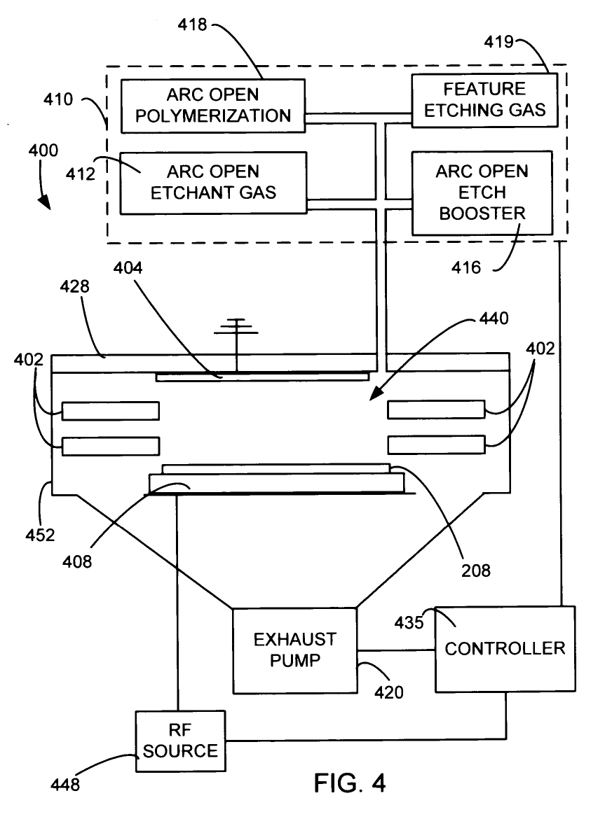

FIG. 4 is a schematic view of a plasma processing chamber 400 that may be used for opening the ARC layer and etching the features in this example. The plasma processing chamber 400 comprises confinement rings 402, an upper electrode 404, a lower electrode 408, a gas source 410, and an exhaust pump 420. For the ARC opening step, the gas source 410 comprises an ARC open etchant gas source 412, an ARC open etch booster gas source 418, an ARC open polymerization gas source 418, and an gas source for etching features in the etch layer 419, if the features are etched in the same process chamber. The gas source 410 may comprise additional gas sources. Within plasma processing chamber 400, the substrate 208 is positioned upon the lower electrode 408. The lower electrode 408 incorporates a suitable substrate chucking mechanism (e.g., electrostatic, mechanical clamping, or the like) for holding the substrate 208. The reactor top 428 incorporates the upper electrode 404 disposed immediately opposite the lower electrode 408. The upper electrode 404, lower electrode 408, and confinement rings 402 define the confined plasma volume. Gas is supplied to the confined plasma volume by the gas source 410 and is exhausted from the confined plasma volume through the confinement rings 402 and an exhaust port by the exhaust pump 420. An RF source 448 is electrically connected to the lower electrode 408. The upper electrode 404 is grounded. Chamber walls 452 surround the confinement rings 402, the upper electrode 404, and the lower electrode 408. The RF source 448 may comprise a 27 MHz power source and a 2 MHz power source. An Exelan 2300™, which is made by LAM Research Corporation™ of Fremont, Calif., was used in this example of the invention. Different combinations of connecting RF power to the electrode are possible in other embodiments, such as having an RF source connected to the upper electrode 404.

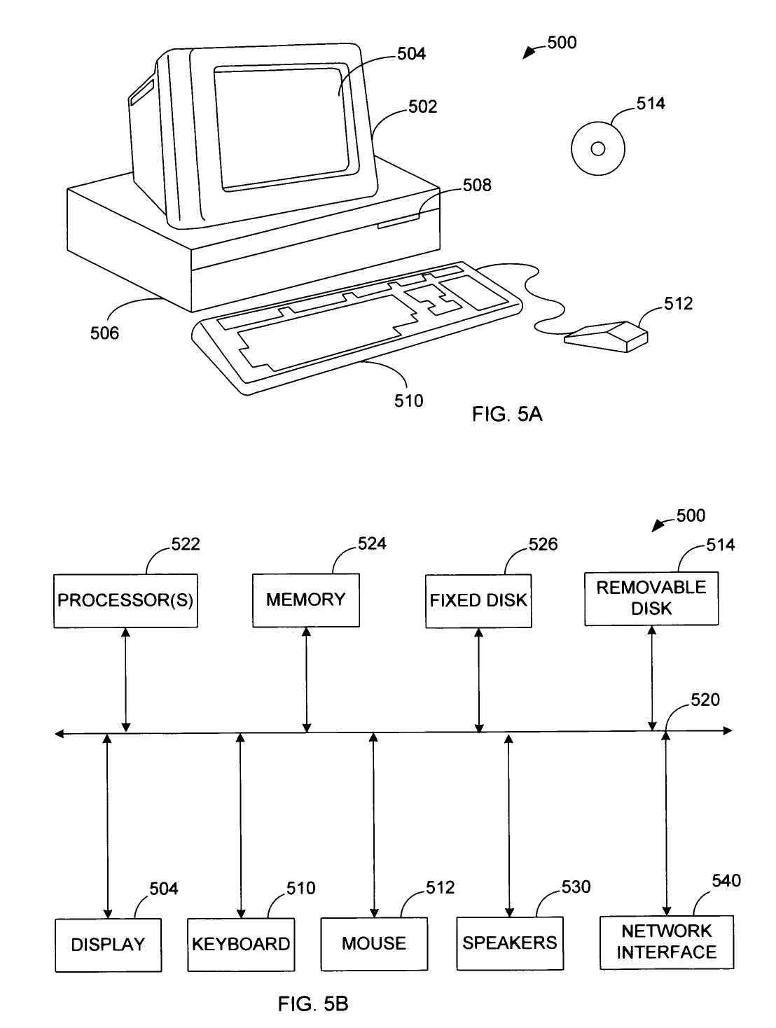

FIGS. 5A and 5B illustrate a computer system 500, which is suitable for implementing a controller 435 used in embodiments of the present invention. FIG. 5A shows one possible physical form of the computer system. Of course, the computer system may have many physical forms ranging from an integrated circuit, a printed circuit board, and a small handheld device up to a huge super computer. Computer system 500 includes a monitor 502, a display 504, a housing 506, a disk drive 508, a keyboard 510, and a mouse 512. Disk 514 is a computer-readable medium used to transfer data to and from computer system 500.

FIG. 5B is an example of a block diagram for computer system 500. Attached to system bus 520 is a wide variety of subsystems. Processor(s) 522 (also referred to as central processing units or CPUs) are coupled to storage devices, including memory 524. Memory 524 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 526 is also coupled bi-directionally to CPU 522; it provides additional data storage capacity and may also include any of the computer-readable media described below. Fixed disk 526 may be used to store programs, data, and the like and is typically a secondary storage medium (such as a hard disk) that is slower than primary storage. It will be appreciated that the information retained within fixed disk 526 may, in appropriate cases, be incorporated in standard fashion as virtual memory in memory 524. Removable disk 514 may take the form of any of the computer-readable media described below.

CPU 522 is also coupled to a variety of input/output devices, such as display 504, keyboard 510, mouse 512 and speakers 530. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 522 optionally may be coupled to another computer or telecommunications network using network interface 540. With such a network interface, it is contemplated that the CPU might receive information from the network, or might output information to the network in the course of performing the above-described method steps. Furthermore, method embodiments of the present invention may execute solely upon CPU 522 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

In this example, for the ARC open the etchant gas comprises 75 sccm N₂ and 50 sccm H₂. The ARC open polymerization gas comprises 200 sccm CO and 6 sccm CH₃F. The ARC open etch booster gas comprises 3 sccm O₂. The chamber pressure is set to 260 mTorr. The power provided by the lower electrode is 0 Watts at 27 MHz and 600 Watts at 2 MHz. The power provided during this step is kept low to reduce the removal of any of the photoresist mask 220. This ARC open gas mixture which uses H₂ and N₂ as the ARC open etchant gases is highly selective for etching BARC with respect to silicon oxide. This high selectivity is defined as being greater than 20:1. More preferably, the ARC open etch to silicon oxide selectivity is greater than 50:1. Most preferably, the ARC open selectivity is greater than infinity, so that there is no etching of the silicon oxide during the ARC open. Preferably, the lower electrode is kept at a temperature between −20° and 40° C.

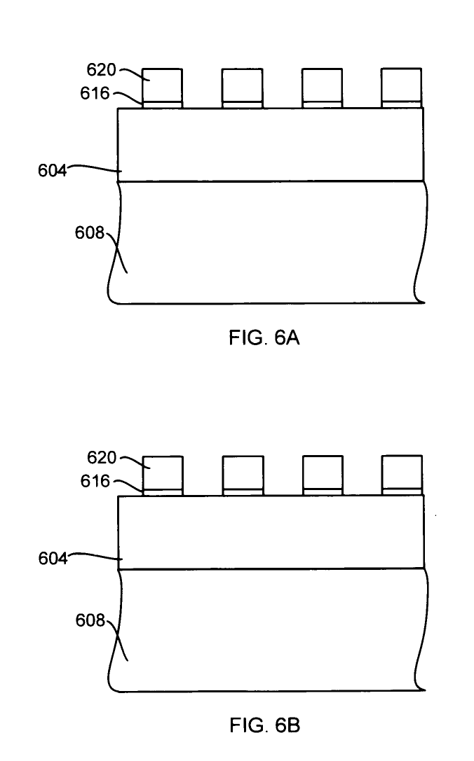

FIG. 6A is a schematic cross-sectional view of a part of an etch layer near the center of a wafer after ARC opening is performed using this example. FIG. 6B is a schematic cross-sectional view of a part of an etch layer near the edge of a wafer after ARC opening is performed using this example. The photoresist mask 620 is protected to minimize damage to the photoresist mask 620 near both the center and edge of the wafer, to increase uniformity.

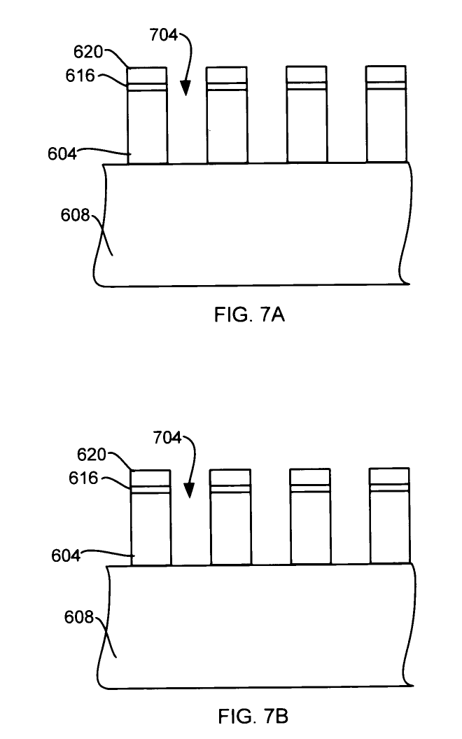

Using the structures shown in FIG. 6A and FIG. 6B, features may be etched into the etch layer, which may result in features 704 as illustrated in FIG. 7A and FIG. 7B, where FIG. 7A is a schematic cross-sectional view of a part of an etch layer near the center of a wafer after a features are etched in the layer and FIG. 7B is a schematic cross-sectional view of a part of an etch layer near the edge of a wafer. The inventive ARC open allows the formation of more uniform features and reduces line edge roughness.

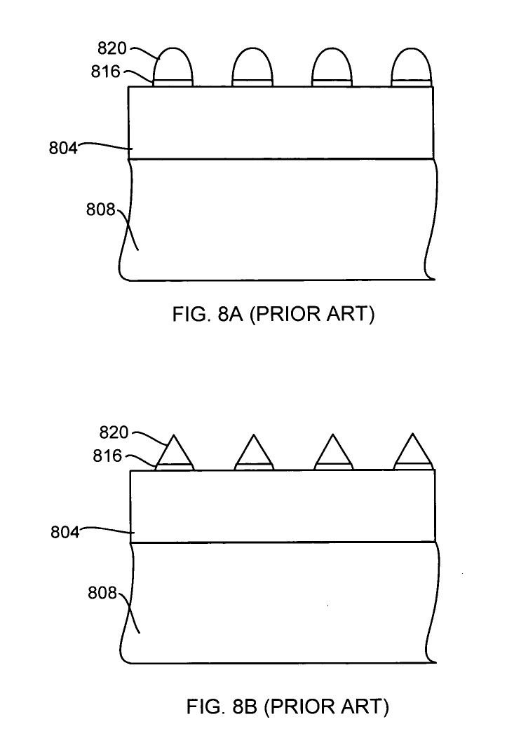

FIG. 8A is a schematic cross-sectional view of a part of an etch layer 804 over a substrate 808 near the center of a wafer after ARC opening is performed using a prior art process. FIG. 8B is a schematic cross-sectional view of a part of an etch layer near the edge of a wafer after ARC opening is performed using a prior art process. Part of the photoresist mask 820 over an ARC layer 816 has been removed during the ARC open process. This is illustrated by the non-rectangular cross-sectional view of the parts of the photoresist mask 820 for both the center and the edge of the wafer, as shown in FIG. 8A and FIG. 8B. In addition, the erosion of the photoresist during the ARC open process of this example of the prior art is not uniform between the center of the wafer and the edge of the wafer. This is illustrated by the difference in the cross-sectional views of the photoresist mask 820 between the center of the wafer, shown in FIG. 8A, and the edge of the wafer, shown in FIG. 8B. In this example of the prior art, more of the photoresist mask is eroded near the edge of the wafer than the center of the wafer.

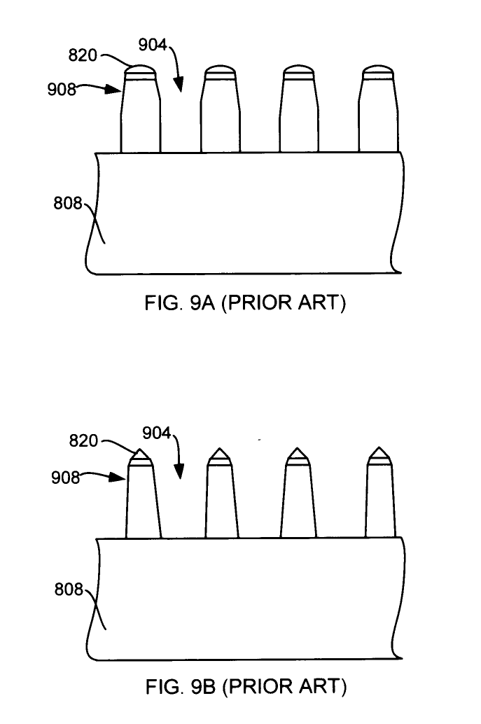

Using the structures shown in FIG. 8A and FIG. 8B, features may be etched into the etch layer, which may result in features 904 as illustrated in FIG. 9A and FIG. 9B, where FIG. 9A is a schematic cross-sectional view of a part of an etch layer near the center of a wafer after a features are etched in the etch layer and FIG. 9B is a schematic cross-sectional view of a part of an etch layer near the edge of a wafer. The erosion of the photoresist near the center of the wafer causes some line edge roughening 908 on the sides of the features 904, as shown in FIG. 9A. The increased erosion of the photoresist near the edge of the wafer causes increased line edge roughening 912 on the sides of the features 904, causing less uniform etch results over the surface of the wafer.

Preferably, the ARC layer is an organic material, since the preferred ARC open recipe is known to open layers of organic material. Therefore, BARC, which is an organic ARC, is used in the preferred embodiment of the invention. The inventive ARC open is able to slowly etch an organic ARC such as BARC, but since the ARC is thin, the slow etch is sufficient. The inventive ARC open recipe is not able etch inorganic layers or etches inorganic silicon based layers so much slower than organic layers that attempting to etch a thin ARC inorganic layer may be too time consuming. Having an etch that is able to etch an organic layer but unable to etch an inorganic layer at a desirable speed allows for the high etch selectivity for etching an organic ARC over an inorganic dielectric layer.

Table 1 provides preferred, more preferred, and most preferred ranges for the break through etch.

TABLE 1

| | Preferred Range | | More Preferred | | Most Preferred | |
|---|---|---|---|---|---|---|
| N₂ | 30-110 | sccm | 50-90 | sccm | 60-80 | sccm |
| H₂ | 20-80 | sccm | 30-70 | sccm | 40-60 | sccm |
| CO | 50-500 | sccm | 100-400 | sccm | 150-300 | sccm |
| CH₃F | 1-16 | sccm | 2-10 | sccm | 4-8 | sccm |
| 27 MHz Power | 0-1000 | Watts | 0-500 | Watts | 0-200 | Watts |
| 2 MHz Power | 100-1000 | Watts | 100-600 | Watts | 200-600 | Watts |
| Pressure | 50-500 | mTorr | 100-400 | mTorr | 200-300 | mTorr |

| | | | |
|---|---|---|---|
| Flow ratio CO:CH₃F | 70:1-20:1 | 60:1-30:1 | 50:1-40:1 |
| Temperature | 20° C. | 20° C. | 20° C. |

While this invention has been described in terms of several preferred embodiments, there are alterations, permutations, modifications and various substitute equivalents, which fall within the scope of this invention. It should also be noted that there are many alternative ways of implementing the methods and apparatuses of the present invention. It is therefore intended that the following appended claims be interpreted as including all such alterations, permutations, modifications, and various substitute equivalents as fall within the true spirit and scope of the present invention.

What is claimed is:

1. A method for etching a layer through a photoresist mask with an ARC layer between the layer to be etched and the photoresist mask over a substrate, comprising:
placing the substrate into a processing chamber;
providing an ARC open gas mixture into the processing chamber, wherein the ARC open gas mixture comprises:
an etchant gas; and
a polymerization gas comprising CO and CH₃F;
forming an ARC open plasma from the ARC open gas mixture;
etching the ARC layer with the ARC open plasma until the ARC layer is opened; and
stopping the ARC open gas mixture before the layer to be etched is completely etched.

2. The method, as recited in claim 1, wherein ARC open plasma highly selectively etches the ARC with respect to the layer to be etched.

3. The method, as recited in claim 2, wherein the flow rate of CO is at least 150 sccm.

4. The method, as recited in claim 3, wherein the ARC open gas mixture further comprises an etch rate booster, wherein the etch rate booster is O₂.

5. The method, as recited in claim 4, wherein the layer to be etched is a dielectric layer and wherein the etchant gas comprises at least one of an N₂ and H₂ mixture and CF₄.

6. The method, as recited in claim 5, wherein combined thicknesses of the seed silicon layer and silicon germanium layer is between 10 and 50 nanometers.

7. The method, as recited in claim 6, further comprising providing a photoresist mask over the stack.

8. The method, as recited in claim 7, wherein the photoresist mask is of a 193 or higher generation photoresist.

9. The method, as recited in claim 8, wherein the ARC layer is of an organic material.

10. The method, as recited in claim 2, wherein the ARC layer is of an organic material and wherein the photoresist mask is of a 193 or higher generation photoresist.

11. The method, as recited in claim 1, wherein the ARC layer is of an organic material and wherein the photoresist mask is of a 193 or higher generation photoresist and wherein the ARC open plasma etches the ARC with respect to the layer to be etched with a selectivity greater than 50:1.

12. The method, as recited in claim 11, wherein the flow rate of CO is at least 150 sccm, and wherein the layer to be etched is silicon oxide.

13. The method, as recited in claim 12, wherein the ARC open gas mixture further comprises an etch rate booster, wherein the etch rate booster is O₂.

14. The method, as recited in claim 1, wherein the ARC open plasma does not etch the layer to be etched.

15. The method, as recited in claim 14, wherein the ARC layer is of an organic material and wherein the photoresist mask is of a 193 or higher generation photoresist and the layer to be etched is silicon oxide.

16. A semiconductor device formed by the method of claim 1.

17. An apparatus with computer readable media for performing the method of claim 1.

18. A method for forming a semiconductor device, comprising:
placing a layer to be etched over a substrate;
forming an organic ARC layer over the layer to be etched;
forming a photoresist mask over the ARC layer;
placing the substrate into a processing chamber;
providing an ARC open gas mixture into the processing chamber, wherein the ARC open gas mixture comprises:
an etchant gas; and
a polymerization gas comprising CO and CH₃F;
forming an ARC open plasma from the ARC open gas mixture;
etching the ARC layer with the ARC open plasma until the ARC layer is opened;
stopping the ARC open gas mixture, so that none of the layer to be etched is etched by the ARC open plasma;
providing an etch plasma different than the ARC open plasma; and
etching the layer to be etched with the etch plasma.

19. The method, as recited in claim 18, wherein the ARC open gas mixture further comprises an etch rate booster, wherein the etch rate booster is O₂.

20. The method, as recited in claim 4, wherein the layer to be etched is a dielectric layer and wherein the etch plasma is formed from an etchant gas comprising at least one of an N₂ and H₂ mixture and CF₄.
